(19) United States
(12) Patent Application Publication
(10) Pub. No.: US 2021/0088361 A1
(43) Pub. Date: Mar. 25, 2021

(54) SENSOR DEVICE, OPERATING DEVICE AND HOUSEHOLD APPLIANCE HAVING THE OPERATING DEVICE

(71) Applicant: DIEHL AKO STIFTUNG & CO. KG, WANGEN (DE)

(72) Inventors: JAKUB BETIUK, LOWICZ (PL); MICHAL SIESICKI, WROCLAW (PL)

(21) Appl. No.: 17/024,240

(22) Filed: Sep. 17, 2020

(30) Foreign Application Priority Data
Sep. 20, 2019 (DE) 102019006611
Dec. 20, 2019 (DE) 102019008977

(51) Int. Cl. G01D 5/241; H01H 9/02

(52) U.S. Cl. CPC G01D 5/2417; H01H 9/0271

(57) ABSTRACT

A sensor device which can be used, for example, for an operating device, for example of an electronic household appliance, in order to detect a movement and/or position of a first component relative to a second component. The first component can be moved about a or in the direction of an axis of movement along a movement path, includes a sensor electrode arrangement on the second component and a signal element on the first component opposite and at a distance to the sensor electrode arrangement. The signal element has electrically conductive sections and electrically non-conductive sections, as well as a sensor control system for inputting sensor signals and receiving measurement signals at/from the sensor electrode arrangement and an evaluation unit for determining a movement and/or position of the first component relative to the second component based on the measurement signals of the sensor control system.

### CROSS-REFERENCE TO RELATED APPLICATION

This application claims the priority, under 35 U.S.C. § 119, of German patent applications DE 10 2019 006 611, filed Sep. 20, 2019 and DE 10 2019 008 977, filed Dec. 20, 2019; the prior applications are herewith incorporated by reference in their entirety.

### BACKGROUND OF THE INVENTION

### Field of the Invention

The present invention relates to a sensor device for detecting a movement and/or position of a first component relative to a second component as well as an operating device, in particular an operating device for an electronic household appliance with a sensor device of this type.

Operating devices often have rotatable or displaceable switching devices which are arranged at a cover plate and the movement and/or position of which is detected by a sensor device. Conventional sensor devices generally have more-or-less complex sensor systems for detecting and evaluating an encoder which is provided on the switching device.

### BRIEF SUMMARY OF THE INVENTION

The object of the invention is to create a sensor device with a simple and cost-effective structure for detecting a movement and/or position of a first component relative to a second component.

This object is achieved by a sensor device with the features of the independent claim. Particularly advantageous configurations and developments of the invention are the subject matter of the dependent claims.

The sensor device according to the invention detects a movement and/or position of a first component relative to a second component. The first component is spaced apart from the second component and the first component can be moved about a or in the direction of an axis of movement along a movement path which runs perpendicular to the distance direction between the two components. The sensor device has a first sensor electrode which is arranged on the second component on a side which faces the first component and runs along the entire movement path and at least one second sensor electrode which is arranged on the second component adjacent to the first sensor electrode in the movement path at a distance to the first sensor electrode and extends over a part of the movement path. A signal element is provided and is arranged on the first component on a side which faces the second component at a distance to the second component and has an electrically conductive first electrode section opposite the first sensor electrode and a second electrode section opposite the at least one second sensor electrode. The first electrode section and the second electrode section are electrically connected to one another and the second electrode section includes at least one electrically conductive part and at least one electrically non-conductive part. A sensor control system with a sensor signal generator for inputting a sensor signal at at least one of the at least one second sensor electrode and with a measurement signal receiver for receiving a measurement signal at the first sensor electrode, is provided. An evaluation unit is provided for determining a movement and/or position of the first component relative to the second component based on the measurement signals of the sensor control system.

The concept of this sensor device is in particular based on the knowledge that a capacitance between two electrodes depends on the relative positioning of the two electrodes to one another. As represented in FIG. 4A by way of example, two electrodes E1 and E2 which are positioned at a distance to one another and precisely opposite one another form a capacitor with a capacitance value Ca by way of the maximum overlap. If the one electrode E1 is displaced relative to the other electrode E2, as illustrated in FIG. 4B by way of example, the overlapping area between the two electrodes E1, E2 is reduced and a capacitor with a capacitance value Cb smaller than Ca is thus formed. Measuring the capacitance between two electrodes therefore makes it possible to identify their relative position or change in position relative to one another in a simple manner.

Based on this basic concept, the sensor device of the invention is structured in such a way that a sensor signal, which is provided at a second sensor electrode, is transmitted to the first sensor electrode via a capacitance between the second sensor electrode and the second electrode section of the signal element and a further capacitance between the first electrode section of the signal element and the first sensor electrode and is received there as a measurement signal. The distance between the sensor electrodes and the signal element remains unchanged in the case of a movement of the first component along the movement path perpendicular to the distance direction between the two components. However, owing to the at least one electrically non-conductive part in the second electrode section of the signal element, the overlap between the electrically conductive part in the second electrode section and the second sensor electrode is changed if the signal element is moved in a direction perpendicular to the connection direction relative to the sensor electrodes, so that the one capacitance between the second sensor electrode and the second sensor section of the signal element is also changed. By contrast, the further capacitance between the first electrode section of the sensor element and the first sensor electrode remains unchanged, since the first sensor electrode extends away across the entire movement path and the first electrode section of the signal element is completely electrically conductive. By changing the one capacitance, the measurement signal arriving at the first sensor electrode is also changed, so that, by evaluating the measurement signal received, an overlap between the electrically conductive part in the second electrode section and the second sensor electrode and thus a relative position or a change in position of the signal element relative to the sensor electrodes can be inferred, which corresponds to a relative position or movement of the first component to the second component. In contrast to conventional sensor devices, neither complex sensor systems nor active sensors are required on the movable components for this effective and reliable sensor device, but rather only a few simple electrodes. The first and second sensor electrodes can simply be directly on a printed circuit board, for example, which also supports the sensor control system.

Preferably, at least two second sensor electrodes are provided on the second component adjacent to the first sensor electrode in the movement path at a distance to the first sensor electrode, which sensor electrodes each extend over a part of the movement path and are electrically separated from one another. In this case, the sensor signal generator of the sensor control system inputs a sensor signal preferably alternately at the at least two second sensor electrodes. The accuracy of the evaluation results can be increased by the signal transmission described above at a plurality of positions. The more second sensor electrodes are provided, the greater the number of identifiable, absolute positions of the first component relative to the second component. The plurality of second sensor electrodes are in each case preferably the same size.

Determining a movement and/or position preferably contains at least one parameter which is selected from an absolute position, a relative position, a position change measurement, a movement direction and a movement speed.

The sensor signal generator of the sensor control system preferably generates an alternating sensor signal, preferably a sinusoidal sensor signal which can also be described as an AC sensor signal.

An insulating element is preferably provided between the first sensor electrode and the at least one second sensor electrode. Electrically insulating the second sensor electrodes from the first sensor electrode makes it possible to suppress a capacitive coupling of the second sensor electrodes directly to the first sensor electrode and thus to avoid a disturbance in the measurement signal at the first sensor electrode.

In one embodiment variant of the invention, the second electrode section of the signal element has a large area electrode as the electrically conductive part which is connected to the first electrode section in an electrically conductive manner (is made in one piece, for example) and at least one or a plurality of gaps as electrically non-conductive parts in the direction of the movement path.

In a different embodiment variant of the invention, the second electrode section of the signal element has one or a plurality of electrodes as electrically conductive parts in the direction of the movement path, which electrodes are connected to the first conductive electrode part.

In one application of the invention, the sensor device can be used for a design in which the first component is rotatable about an axis of rotation relative to the second component. In this case, a preferred configuration of the invention is such that the first sensor electrode is circular or annular in shape and the at least one second sensor electrode is annular sector-shaped or circular sector-shaped and is positioned in a radial direction inside or outside the first sensor electrode, and the first electrode section of the signal element is circular or annular in shape and the at least one electrically non-conductive part or the at least one electrically conductive part of the second electrode section of the signal element is annular sector-shaped or circular sector-shaped and is positioned in a radial direction inside or outside the first electrode section.

In a different application of the invention, the sensor device can be used for a design in which the first component can be displaced along a thrust axis relative to the second component. In this case, a preferred configuration of the invention is such that the first sensor electrode is linear in shape (e.g. substantially in a straight line or arcuate in shape) and the at least one second sensor electrode is block-shaped and is positioned adjacent to the first sensor electrode; and the first electrode section of the signal element is linear in shape (e.g. substantially in a straight line or arcuate in shape) and the at least one electrically non-conductive part or the at least one electrically conductive part of the second electrode section of the signal element is block-shaped and is positioned adjacent to the first electrode section.

Furthermore, the sensor device can be used for a design in which the first component can additionally be moved by a pressure actuation in the distance direction between the sensor electrodes and the signal element relative to the second component. In this case, a preferred configuration of the invention is such that the evaluation unit detects a change in distance between the sensor electrodes and the signal element further based on the measurement signals of the sensor control system and identifies a pressure actuation of the first component based on the detected change in distance. Depending on the design of the first and second components, the change in distance can mean an increase or reduction in the distance, which causes a significant change in the one capacitance value between the second sensor electrode and the second electrode section of the signal element, one which is more significant than a change in capacitance which is caused by a movement (rotation or displacement).

An operating device is also a subject matter of the invention, which operating device has: a cover plate (e.g. an operating panel) with a user side which faces a user and an internal side which faces away from a user; a switching device with an operating head on the user side of the cover plate, wherein the switching device can be moved about a or in the direction of an axis of movement along a movement path in a plane parallel to the cover plate relative to the cover plate; a supporting plate on the internal side of the cover plate which is orientated substantially parallel to the cover plate; and a sensor device of the invention described above for detecting a movement and/or position of the switching device. In this application, the first and second sensor devices are arranged on a side of the supporting plate (second components in accordance with the description above), the signal element is arranged on a side of a supporting element which is fixedly connected to the operating head of the switching device (first component in accordance with the description above), which supporting element is orientated parallel to the cover plate and is spaced apart from the supporting plate, and the evaluation unit determines a movement and/or position of the switching device based on the measurement signals of the sensor control system.

Regarding the operating principle and the advantages of this operating device, reference is made to the above explanations in relation to the sensor device of the invention.

In one configuration of the invention, the supporting element is connected to the operating head of the switching device via a shaft and the cover plate has an opening through which runs the shaft of the switching device.

In one configuration variant of the invention, the supporting element of the switching device is arranged on a side of the supporting plate which faces the cover plate. In this case, the signal element is provided on the side of the supporting element which faces away from the cover plate and the first and second sensor electrodes are provided on the side of the supporting plate which faces the cover plate.

In a different configuration variant of the invention, the supporting element of the switching device is arranged on a side of the supporting plate which faces away from the cover plate. In this case, the signal element is provided on the side of the supporting element which faces the cover plate and the first and second sensor electrodes are provided on the side of the supporting plate which faces away from the cover plate. If the switching device is a control knob, the supporting element is preferably connected to the operating head of the switching device via a shaft which runs through an opening in the supporting plate.

In one configuration variant of the invention, the switching device is rotatable about an axis of rotation which runs perpendicular to the cover plate. In this case, the sensor device is preferably configured in such a way that the first sensor electrode is circular or annular in shape and the at least one second sensor electrode is annular sector-shaped or circular sector-shaped and is positioned in a radial direction inside or outside the first sensor electrode, and the first electrode section of the signal element is circular or annular in shape and the at least one electrically non-conductive part or the at least one electrically conductive part of the second electrode section of the signal element is annular sector-shaped or circular sector-shaped and is positioned in a radial direction inside or outside the first electrode section.

In a different configuration variant of the invention, the switching device can be displaced along a thrust axis which runs parallel to the cover plate. In this case, the sensor device is preferably configured in such a way that the first sensor electrode is linear in shape (e.g. substantially in a straight line or arcuate in shape) and the at least one second sensor electrode is block-shaped and is positioned adjacent to the first sensor electrode; and the first electrode section of the signal element is linear in shape (e.g. substantially in a straight line or arcuate in shape) and the at least one electrically non-conductive part or the at least one electrically conductive part of the second electrode section of the signal element is block-shaped and is positioned adjacent to the first electrode section.

In a further configuration variant of the invention, the switching device can additionally be moved by a pressure actuation of the operating head in a direction perpendicular to the cover plate relative to the cover plate. In this case, the evaluation unit of the sensor device can preferably detect a change in distance between the first and second sensor electrodes and the signal element further based on the sensor signals of the sensor control system and can identify a pressure actuation of the operating head based on the detected change in distance.

In a further configuration of the invention, the operating device has a plurality of moveable switching devices and a plurality of sensor devices which are each associated with one of the plurality of switching devices. In this case, the plurality of sensor devices can preferably have a common sensor control system with a common sensor signal generator and preferably also a common evaluation unit.

Furthermore, an electronic household appliance with at least one operating device of the invention described above is a subject matter of the invention. The electronic household appliance is, for example, a hob, a stove, a dishwasher, a washing machine, a fridge and/or freezer or the like.

Other features which are considered as characteristic for the invention are set forth in the appended claims.

Although the invention is illustrated and described herein as embodied in a sensor device and an operating device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, sectional view of an operating device with a rotatable switching device according to a first exemplary embodiment of the present invention;

FIG. 2A is a perspective plan view of a signal element of the operating device from FIG. 1 according to a first embodiment variant;

FIG. 2B is a perspective plan view of the signal element of the operating device from FIG. 1 according to a second embodiment variant;

FIG. 3 is a perspective plan view of sensor electrodes of the operating device from FIG. 1 in combination with the signal element from FIG. 2;

FIGS. 4A and 4B are perspective views of two electrodes in two different positions relative to one another in order to explain the operating principle of the sensor device according to the invention;

FIG. 5 is a perspective view of the sensor electrodes and the signal element in order to explain the mode of operation of the sensor device;

FIG. 6A are illustrations of two equivalent circuit diagrams of the sensor device of an operating device of the present invention for two different states of the sensor device;

FIG. 6B is an illustration showing signal timing diagrams for a measurement signal and a sensor signal for the two different states of the sensor device according to FIG. 6A according to an exemplary embodiment of the invention;

FIG. 7 is a block diagram showing a structure of an exemplary embodiment of a sensor control system for an operating device of the present invention;

FIG. 8A is a graph showing an example of signal timing diagrams of the different signal levels in the sensor control system from FIG. 7;

FIGS. 8B and 8C are enlarged representations of details Z1 or Z2 of the signal timing diagrams from FIG. 8A;

FIG. 9 is a sectional view of the operating device with the rotatable switching device according to a second exemplary embodiment of the present invention;

FIG. 10 is a sectional view of the operating device with a displaceable switching device according to a third exemplary embodiment of the present invention;

FIG. 11 is a plan view of an embodiment variant of the signal element of the operating device from FIG. 10; and

FIG. 12 is a plan view of an embodiment variant of the sensor electrodes of the operating device from FIG. 10.

### DETAILED DESCRIPTION OF THE INVENTION

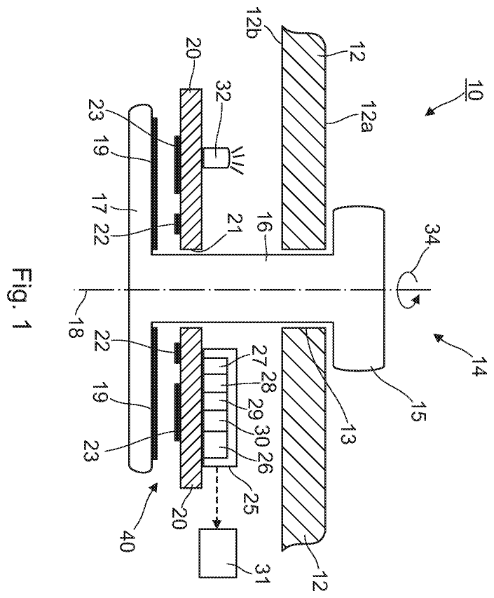

Referring now to the figures of the drawings in detail and first, particularly to FIGS. 1 to 3 thereof, there is shown a structure of an exemplary first exemplary embodiment of an operating device with a rotatable switching device and a sensor device according to the invention is firstly explained in greater detail.

The operating device 10 has a cover plate 12, for example in the form of an operating panel, with a user side 12a which faces a user (above in FIG. 1) and an internal side 12b which faces away from a user (below in FIG. 1). The cover plate 12 additionally has a through-opening 13. The material of the cover plate 12 is, in principle, arbitrary.

The operating device 10 further has a switching device 14. The switching device 14 has an operating head 15 which is positioned on the user side 12a of the cover plate 12 and can therefore be accessed and operated by the user. The switching device 14 further has a shaft 16 which runs from the operating head 15 through the opening 13 in the cover plate 12 to the internal side 12b of the cover plate and runs substantially perpendicular to the cover plate 12. The switching device 14 has a supporting element 17 at the internal end of the shaft 16, which supporting element is connected to the operating head 15 via the shaft 16 in a rotationally fixed manner. The supporting element 17 is configured to be substantially disk-shaped and extends substantially parallel to the cover plate 12. The switching device 14 of this exemplary embodiment is rotatable about an axis of rotation 18 which is orientated substantially perpendicular to the cover plate 12. A rotational actuation 34 of the operating head 15 by a user automatically causes the supporting element 17 to also rotate about the axis of rotation 18. As represented in FIG. 1, a signal element 19 is provided on the side of the supporting element 17 of the switching device which faces the cover plate 12.

The operating device 10 further has a sensor device 40. The sensor device 40 has a supporting plate 20, preferably in the form of a printed circuit board, which is orientated substantially parallel to the cover plate 12. In this exemplary embodiment, the supporting plate 20 is located between the cover plate 12 and the supporting element 17 of the switching device 14. The supporting plate 20 therefore also has a through-opening 21 through which runs the shaft 16 of the switching device 14. In a different embodiment variant of the invention, the supporting plate 20 can also be positioned below the supporting element 17 of the switching device 14.

As represented in FIG. 1, the sensor device 40 has a first sensor electrode 22 and at least one second sensor electrode 23 on the side of the supporting plate 20 which faces the supporting element 17, i.e. in this exemplary embodiment on the side of the supporting plate 20 which faces away from the cover plate 12. The sensor device 40 further has a sensor control system 25, which is preferably assembled on the supporting plate 20, and an evaluation unit 31 which has a microprocessor, for example, and can optionally also be assembled on the supporting plate 20. As indicated in FIG. 1, the sensor control system 25 has a sensor signal generator 26 and a measurement signal receiver 27 and, in this exemplary embodiment, also a signal amplifier 28, a peak-to-peak detector 29 and a comparator 30. The evaluation unit 31 is connected to an appliance control system of the appliance, for example, in/at which the operating device 10 is installed.

Optionally, at least one light-emitting element 32 can also be assembled on the supporting plate 20. In this case, the cover plate 12 is configured to be at least partially transparent, so that the region of the cover plate 12 around the operating head 15 can be back-lit, for example, in order to make it easier for the user to identify the position of the switching device 14 and/or to display status information of the operating device 10.

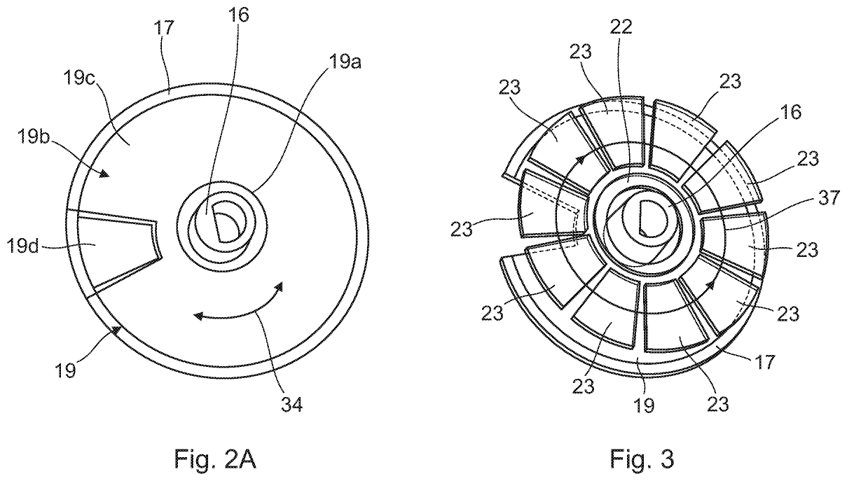

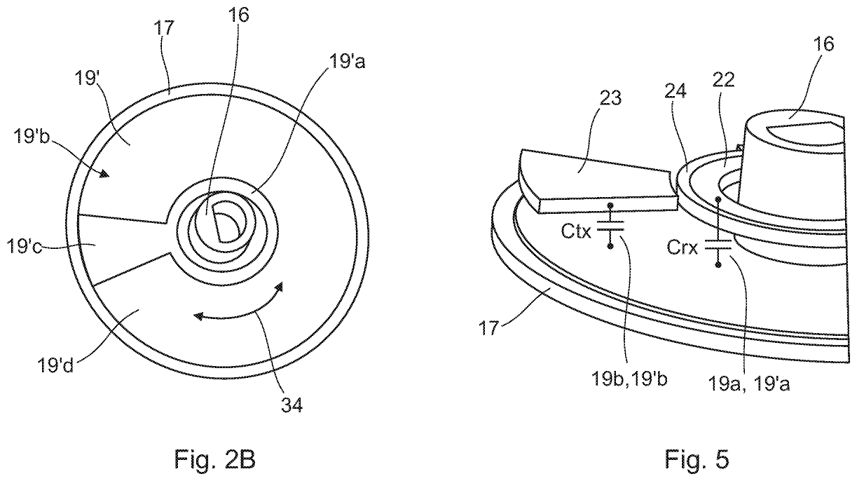

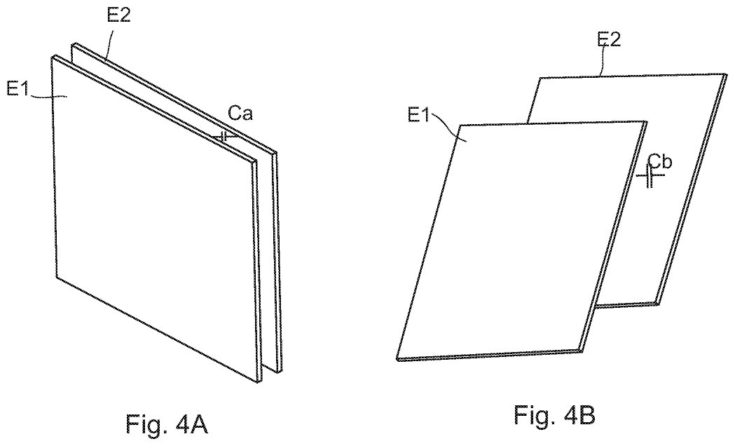

As illustrated in FIG. 2A, the supporting element 17 of the switching device 14 is substantially circular in shape. The signal element 19 includes a first electrode section 19a which runs around the shaft 16 substantially annularly and a second electrode section 19b which runs around the first electrode section substantially annularly. The first electrode section 19a is a fully electrically conductive electrode. In the embodiment variant from FIG. 2A, the second electrode section 19b has an electrically conductive part 19c in the form of a large area electrode which is electrically connected to the first electrode section 19a and extends over a large part of the circumferential direction, and has at least one electrically non-conductive part 19d in the form of a gap.

In the embodiment variant from FIG. 2B, the supporting element 17 of the switching device 14 is also substantially circular in shape. The signal element 19′ includes a first electrode section 19′a which runs around the shaft 16 substantially annularly and a second electrode section 19′b which runs around the first electrode section 19′a substantially annularly. The first electrode section 19′a is a fully electrically conductive electrode. In this embodiment variant, the second electrode section 19′b has at least one electrically conductive part 19′c in the form of an annular sector-shaped electrode which is electrically connected to the first electrode section 19′a and only extends over a limited part of the circumferential direction, and has at least one electrically non-conductive part 19′d which extends over the remaining part of the circumference.

As illustrated in FIG. 3, the first sensor electrode 22 is substantially annular in shape and extends away across the entire rotation zone 37. In this case, the first sensor electrode 22 is positioned opposite the first electrode section 19a, 19′a of the signal element 19, 19′. In this exemplary embodiment, ten second sensor electrodes 23 are provided in total which are each annular sector-shaped and are separated from one another in the circumferential direction and are arranged radially outwardly of the first sensor electrode 22 and in each case at a distance to the first sensor electrode 22. Overall, the second sensor electrodes 23 are positioned opposite the second electrode section 19b, 19′b of the signal element 19, 19′. The first and second sensor electrodes 22, 23 can be formed by a copper layer on the supporting plate or printed circuit board 20, for example. The first and second sensor electrodes 22, 23 are spaced apart from the signal element 19, 19′ on the supporting element 17, for example by approximately 0.5 mm or approximately 1.0 mm.

The number of second sensor electrodes 23 is not limited to this exemplary embodiment. The numbers of electrically non-conductive gaps 19d or of electrically conductive electrodes 19′c of the signal element 19, 19′ are also not limited to this exemplary embodiment.

While in this exemplary embodiment the second sensor electrodes 23 are positioned in a radial direction outside the first sensor electrode 22, this can also be reversed within the scope of the invention, i.e. the second sensor electrodes 23 can be positioned in a radial direction inside the first sensor electrode 22. In this case, the first electrode section 19a, 19′a and the second electrode section 19b, 19′b would then also be reversed on the supporting element 17, so that the first electrode section 19a, 19′a is located opposite the first sensor electrode 22 and the second electrode section 19b, 19′b is located opposite the second sensor electrodes 23.

Referring to FIGS. 5 to 8, the mode of operation of the sensor device will now be explained in greater detail by way of example.

As illustrated in FIG. 5, the first sensor electrode 22 forms a capacitor with a capacitance Crx together with the opposite first electrode section 19a, 19′a of the signal element 19, 19′, and a second sensor electrode 23 forms a capacitor with a capacitance Ctx together with the opposite second electrode section 19b, 19′b of the signal element. While the first and the second electrode section of the signal element 19, 19′ are connected to one another in an electrically conductive manner, the first and second sensor electrodes 22, 23 are spaced apart from one another and preferably additionally electrically insulated from one another by an insulating element 24.

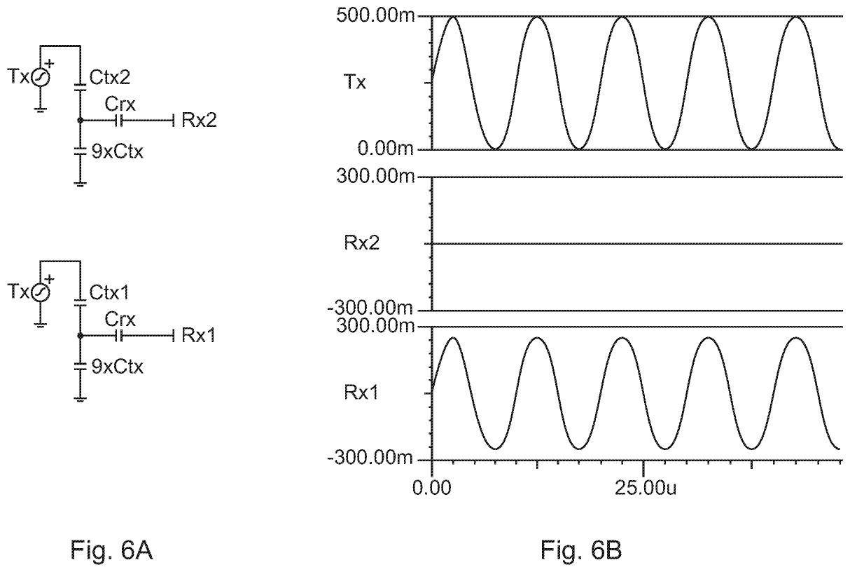

In the bottom part of the picture, FIG. 6A shows an equivalent circuit diagram in the event of the second sensor electrode 23 which is controlled as a transmitter being located opposite an electrically conductive part 19c, 19′c of the signal element 19, 19′. In this case, the sensor signal generator 26 of the sensor control system 25 inputs a sinusoidal sensor signal Tx at the one second sensor electrode 23 which is controlled as a transmitter, as represented by way of example in the top timing diagram from FIG. 6B, while the other nine second sensor electrodes 23 are connected to ground. The sensor signal Tx is then transmitted from the second sensor electrode 23 via the capacitor, which is formed by the second sensor electrode 23 and the opposite electrically conductive part 19c, 19′c of the second electrode section 19b, 19′b of the signal element 19, 19′ and has a capacitance value of Ctx1 in this fully overlapping positioning, and the further capacitor, which is formed by the first sensor electrode 22 and the first electrode section 19a, 19′a of the signal element 19, 19′ and always has a capacitance value of Crx, to the first sensor electrode 22, where it is received by the measurement signal receiver 27 of the sensor control system 25 as a measurement signal Rx1, which is represented by way of example in the bottom timing diagram from FIG. 6B. As shown when comparing the sensor signal Tx to the measurement signal Rx1, the course of the measurement signal Rx1, similarly to the sensor signal, is also sinusoidal and the amplitudes are only slightly reduced.

In the top part of the picture, FIG. 6A shows an equivalent circuit diagram in the event that the second sensor electrode 23 which is controlled as a transmitter is located opposite an electrically non-conductive part 19d, 19′d of the signal element 19, 19′. The sensor signal Tx which is input by the sensor signal generator 26 at the one second sensor electrode 23 which is controlled as a transmitter is then transmitted from the second sensor electrode 23 via the capacitor, which is formed by the second sensor electrode 23 and an offset electrically conductive part 19c, 19′c of the second electrode section 19b, 19′b of the signal element 19, 19′ and has a significantly reduced capacitance value of Ctx2 in this non-overlapping positioning, and the further capacitor, which is formed by the first sensor electrode 22 and the first electrode section 19a, 19′a of the signal element 19, 19′ and always has a capacitance value of Crx, to the first sensor electrode 22, where it is received by the measurement signal receiver 27 of the sensor control system 25 as a measurement signal Rx2, which is represented by way of example in the middle timing diagram from FIG. 6B. As shown when comparing the measurement signals Rx1 and Rx2, the amplitudes of the measurement signal Rx2 are almost eliminated and the measurement signals in the two states described are clearly different, so that the evaluation unit can identify these different positions of the second electrode section 19b, 19′b of the signal element 19, 19′ on the supporting element 17 of the switching device 14 relative to the second sensor electrode 23 in a simple and reliable manner.

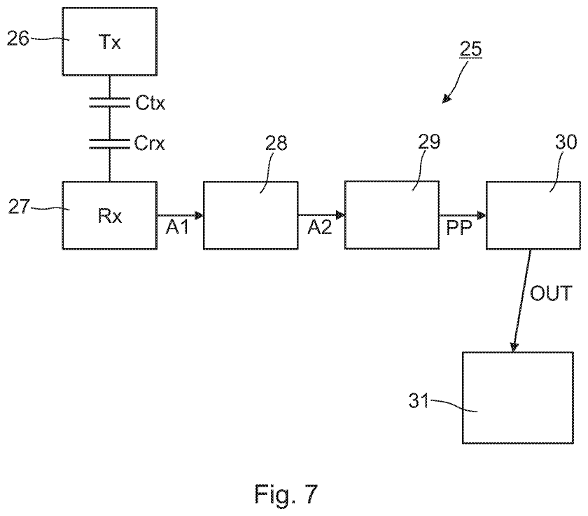

In order for the evaluation unit 31 to evaluate the measurement signals Rx in a simpler manner, the sensor control system 25 preferably carries out additional signal processing, as represented in FIG. 7 by way of example. The sensor signal generator 26 generates the sensor signal Tx and inputs it to a second sensor electrode 23. The measurement signal receiver 27 receives the measurement signal Rx at the first sensor electrode 22 and passes it on to the signal amplifier 28 as a raw signal A1. The signal amplifier 28 then passes on the amplified signal A2 to a peak-to-peak detector 29 which converts the sinusoidal signal A2 into a temporal course of the peak-to-peak distances. This peak-to-peak signal PP is then passed on to a comparator 30 which compares it with a reference value, in order to transmit an output signal OUT to the evaluation unit 31 which specifies the points in time at which the peak-to-peak distances exceed a predetermined threshold value, i.e. the amplitude values are very high, which is only the case in the event of a maximum overlap of the second sensor electrode 23 with the electrically conductive part 19c, 19′c of the second electrode section 19b, 19′b of the signal element 19, 19′.

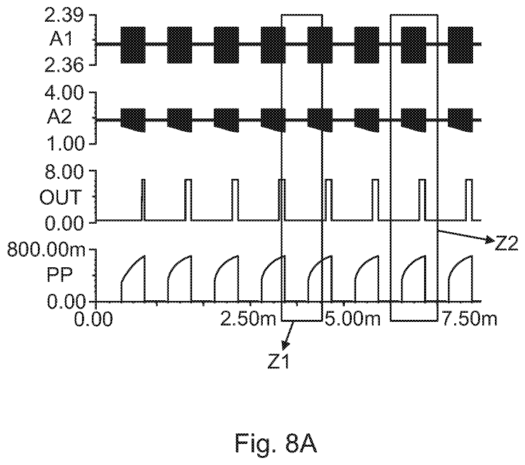

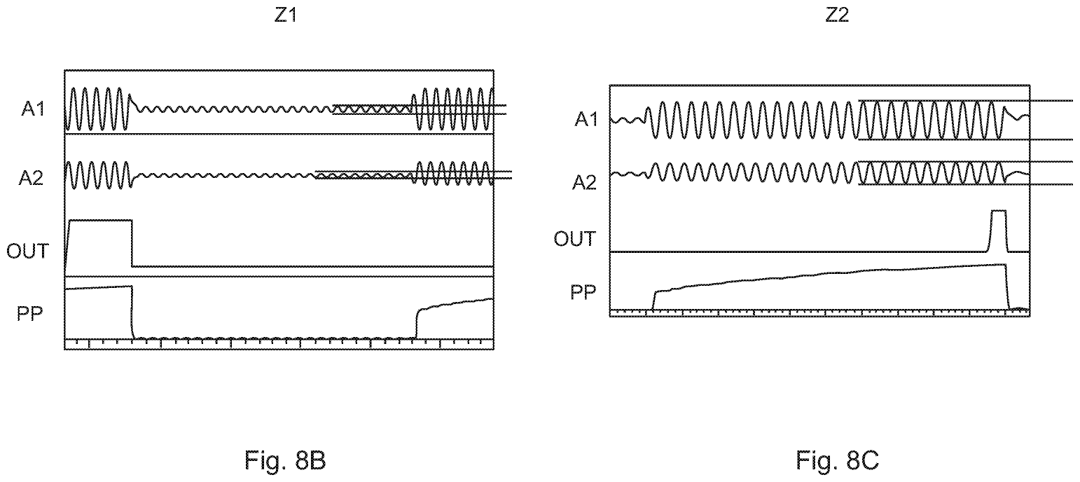

In order to clarify the signal processing described by means of FIG. 7, FIGS. 8A-C show exemplary timing diagrams of the different signal processing stages A1, A2, PP and OUT.

The diagrams from FIGS. 6 to 8 clarify how a movement of the switching device 14 relative to the supporting plate 20 and to the cover plate 12 can be detected by means of a signal transmission from a second sensor electrode 23 to the first sensor electrode 22 via the signal element 19, 19′. If, as in this exemplary embodiment, a plurality of second sensor electrodes 23 are provided on the supporting plate 20, they are controlled alternately by the sensor control system 25 with the sensor signal Tx, while all other second sensor electrodes 23 are each connected to ground. The precision of the movement detection can then be further improved by evaluating the corresponding plurality of measurement signals Rx.

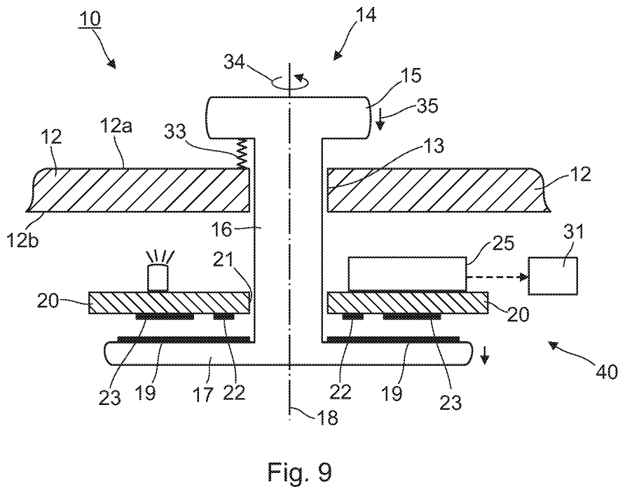

Referring to FIG. 9, the structure of an exemplary second exemplary embodiment of an operating device with a rotatable switching device and a sensor device according to the invention will now be explained. The same or corresponding components are identified with the same reference numbers as in FIG. 1.

The operating device 10 from FIG. 9 is different from the operating device of the first exemplary embodiment in that the switching device 14, in addition to a rotational actuation 34 about an axis of rotation 18, can also experience a pressure actuation 35, by means of which it can be displaced in a direction perpendicular to the cover plate 12. As represented in FIG. 9, the operating device 10 has a spring element 33 which pretensions the operating head 15 of the switching device 14 in the direction away from the user side 12a of the cover plate 12 (upwards in FIG. 9). In the case of a pressure actuation 35 of the operating head 15 by a user, the operating head 15 is pressed in the direction towards the cover plate 12 and thus the supporting element 17 of the switching device 14 is also pressed further away from the internal side 12b of the cover plate 12 (downwards in FIG. 9). As a result, the signal element 19 on the supporting element 17 is further away from the sensor electrodes 22, 23 on the supporting plate 20. As a result, both capacitance values Ctx and Crx are significantly reduced in the case of a pressure actuation 35 of the switching device 14, which causes a significant change in the measurement signal Rx which can be identified in a simple manner by the evaluation unit 31.

Moreover, the second exemplary embodiment from FIG. 9 corresponds to the first exemplary embodiment. In particular, the sensor device 40 of the operating device 10 also corresponds to that of the operating device of the first exemplary embodiment, except for the additional identification of the pressure actuation 35.

In an alternative exemplary embodiment (not represented), the supporting plate 20 with the sensor electrodes 22, 23 can also be arranged below the supporting element 17 of the switching device 14. In this case, a pressure actuation 35 of the switching device 14 would lead to a reduction in the distance of the signal element 19 from the sensor electrodes 22, 23, up to the point of contact, which also causes a significant change in the measurement signal Rx which can be identified in a simple manner by the evaluation unit 31.

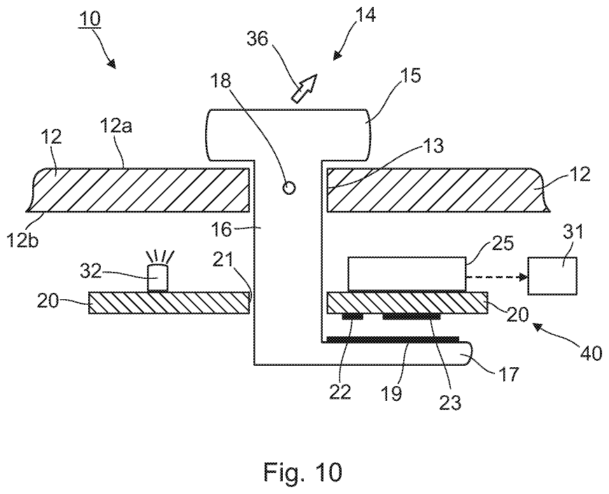

Referring to FIGS. 10 to 12, the structure of an exemplary third exemplary embodiment of an operating device with a switching device and a sensor device according to the invention will now be explained. The same or corresponding components are identified with the same reference numbers as in the first exemplary embodiment.

The operating device 10 from FIGS. 10 to 12 is different from the operating device of the first exemplary embodiment in that the switching device 14 is not rotatable about an axis of rotation, but rather can be displaced along a thrust axis 18 which runs parallel to the cover plate 12. The opening 13 in the cover plate is designed as a correspondingly long slot so that the switching device can be moved along a thrust line 37. As represented in FIG. 10, the signal element 19 and the sensor electrodes 22, 23 are only arranged on one side of the shaft 16. However, they could also optionally be arranged on two opposite sides of the shaft 16.

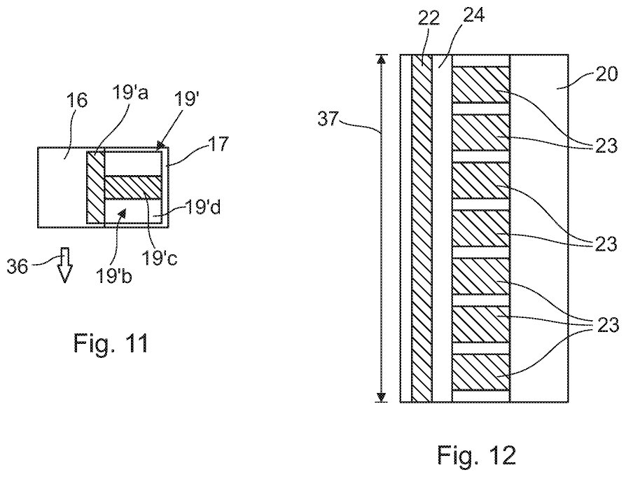

As illustrated in FIG. 11, the supporting element 17 of the switching device 14 is substantially rectangular in shape. The signal element 19′ includes a first electrode section 19′a which runs substantially in a straight line parallel to the thrust axis 18 adjacent to the shaft 16, and a second electrode section 19′b which is located substantially in a straight line adjacent to the first electrode section 19′a. In this exemplary embodiment, the second electrode section 19′b has an electrically conductive part 19′c in the form of an electrode which runs substantially perpendicular to the first electrode section 19′a and is electrically connected to the first electrode section 19′a, and has two electrically non-conductive parts 19′d which are located in front of and behind the electrodes 19′c in the direction of the thrust direction 18.

As represented in FIG. 12, the first sensor electrode 22 is configured in a straight line (generally linear in shape) and extends along the entire thrust line 37. In this case, during a thrust actuation 36 of the switching device 14, the first electrode section 19′a of the signal element 19′ is moved relative to the first sensor electrode 22. In this exemplary embodiment, a total of seven second sensor electrodes 23 are provided which are each block-shaped and are separated from one another in the direction of the thrust line 37 and are arranged adjacent to the first sensor electrode 22 and in each case at a distance to the first sensor electrode 22 in the direction perpendicular to the thrust line 37. In this case, during a thrust actuation 36 of the switching device 14, the second electrode section 19′a of the signal element 19′ with the one electrode 19′c is moved relative to the second sensor electrodes 23.

The number of second sensor electrodes 23 is not limited to this exemplary embodiment. The numbers of electrodes 19′c of the signal element 19′ are also not limited to this exemplary embodiment.

Moreover, the structure and mode of operation of the operating device of this third exemplary embodiment correspond to those of the first exemplary embodiment.

The above-mentioned second exemplary embodiment and the above-mentioned third exemplary embodiment can also be combined with one another as a further exemplary embodiment of the invention. In other words, the switching device 14 can additionally be moved by a pressure actuation even in the operating device from FIGS. 10-12 with a displaceable switching device.

The following is a summary list of reference numerals and the corresponding structure used in the above description of the invention:
10 operating device
12 cover plate
12a/12b user side/internal side
13 opening
14 switching device
15 operating head
16 shaft
17 supporting element
18 axis of movement (e.g. axis of rotation or thrust axis)
19, 19′ signal element
19a, 19′a first electrode section
19b, 19′b second electrode section
19c, 19′c electrically conductive part
19d, 19′d electrically non-conductive part
20 supporting plate (in particular printed circuit board)
21 opening
22 first sensor electrode
23 second sensor electrodes
24 insulating element
25 sensor control system
26 sensor signal generator
27 measurement signal receiver
28 signal amplifier
29 peak-to-peak detector
30 comparator
31 evaluation unit
32 light-emitting element
33 spring element
34 rotational actuation
35 pressure actuation
36 thrust actuation
37 movement path (e.g. rotational zone or thrust line)
40 sensor device

1. A sensor device for detecting a movement and/or position of a first component relative to a second component, wherein the first component is spaced apart from the second component and the first component can be moved about a or in a direction of an axis of movement along a movement path running perpendicular to a distance direction between the first and second components, the sensor device comprising:
a first sensor electrode being disposed on the second component on a side facing the first component and runs along an entire length of the movement path;
at least one second sensor electrode being disposed on the second component adjacent to said first sensor electrode in the movement path at a distance to said first sensor electrode and extending over a part of the movement path;
a signal element disposed on the first component on a side facing the second component at a distance to the second component and having an electrically conductive first electrode section opposite said first sensor electrode and a second electrode section opposite said at least one second sensor electrode, wherein said electrically conductive first electrode section and said second electrode section are electrically connected to one another and said second electrode section having at least one electrically conductive part and at least one electrically non-conductive part;
a sensor control system with a sensor signal generator for inputting a sensor signal at at least one of said at least one second sensor electrode and with a measurement signal receiver for receiving a measurement signal at said first sensor electrode; and
an evaluation unit for determining the movement and/or position of the first component relative to the second component based on measurement signals of said sensor control system.

2. The sensor device according to claim 1, wherein:
said at least one second sensor electrode is one of at least two second sensor electrodes disposed on the second component adjacent to said first sensor electrode in the movement path at a distance to said first sensor electrode, said at least two second sensor electrodes each extend over a part of the movement path and are electrically separated from one another; and
said sensor signal generator of said sensor control system inputs the sensor signal alternately at said at least two second sensor electrodes.

3. The sensor device according to claim 1, wherein said sensor signal generator of said sensor control system generates an alternating sensor signal.

4. The sensor device according to claim 1, further comprising an insulating element disposed between said first sensor electrode and said at least one second sensor electrode.

5. The sensor device according to claim 1, wherein, if the first component is rotatable about an axis of rotation relative to the second component:
said first sensor electrode is circular or annular in shape and said at least one second sensor electrode is annular sector-shaped or circular sector-shaped and is positioned in a radial direction inside or outside of said first sensor electrode; and
said electrically conductive first electrode section of said signal element is circular or annular in shape and said at least one electrically non-conductive part or said at least one electrically conductive part of said second electrode section of said signal element is annular sector-shaped or circular sector-shaped and is positioned in a radial direction inside or outside said electrically conductive first electrode section.

6. The sensor device according to claim 1, wherein, if the first component can be displaced relative to the second component along a thrust axis:
said first sensor electrode is linear in shape and said at least one second sensor electrode is block-shaped and is positioned adjacent to said first sensor electrode; and
said electrically conductive first electrode section of said signal element is linear in shape and said at least one electrically non-conductive part or said at least one electrically conductive part of said second electrode section of said signal element is block-shaped and is positioned adjacent to said electrically conductive first electrode section.

7. The sensor device according to claim 1, wherein, if the first component can additionally be moved by a pressure actuation in a distance direction between said first and second sensor electrodes and said signal element relative to the second component, said evaluation unit detects a change in distance between said first and second sensor electrodes and said signal element further based on the measurement signals of said sensor control system and identifies the pressure actuation of the first component based on a detected change in distance.

8. An operating device, comprising:
a cover plate with a user side facing a user and an internal side facing away from the user;
a switching device with an operating head on said user side of said cover plate, wherein said switching device can be moved about a or in a direction of an axis of movement along a movement path in a plane parallel to said cover plate relative to said cover plate, said switching device further having a supporting element;
a supporting plate on said internal side of said cover plate which is orientated parallel to said cover plate;
a sensor device according to claim 1 for detecting a movement and/or position of said switching device; and
said first and second sensor electrodes are disposed on a side of said supporting plate, said signal element is disposed on a side of said supporting element which is fixedly connected to said operating head of said switching device, said supporting element is orientated parallel to said cover plate and is spaced apart from said supporting plate, and said evaluation unit determining a movement and/or position of said switching device based on the measurement signals of said sensor control system.

9. The operating device according to claim 8, wherein:
said switching device has a shaft and said supporting element is connected to said operating head of said switching device via said shaft; and
said cover plate has an opening formed therein through which runs said shaft of said switching device.

10. The operating device according to claim 8, wherein:
said supporting element of said switching device is disposed on a side of said supporting plate which faces said cover plate; and
said signal element is provided on a side of said supporting element which faces away from said cover plate, and said first and second sensor electrodes are provided on said side of said supporting plate which faces said cover plate.

11. The operating device according to claim 8, wherein:
said supporting element of said switching device is disposed on a side of said supporting plate which faces away from said cover plate; and
said signal element is provided on a side of said supporting element which faces said cover plate, and said first and second sensor electrodes are provided on said side of said supporting plate which faces away from said cover plate.

12. The operating device according to claim 8, wherein:
said switching device is rotatable about an axis of rotation which runs perpendicular to said cover plate;
said supporting element is rotatable about the axis of rotation relative to said supporting plate;
said first sensor electrode is circular or annular in shape and said at least one second sensor electrode is annular sector-shaped or circular sector-shaped and is positioned in a radial direction inside or outside of said first sensor electrode; and
said electrically conductive first electrode section of said signal element is circular or annular in shape and said at least one electrically non-conductive part or said at least one electrically conductive part of said second electrode section of said signal element is annular sector-shaped or circular sector-shaped and is positioned in a radial direction inside or outside said electrically conductive first electrode section.

13. The operating device according to claim 8, wherein:
said switching device is rotatable about an axis of rotation which runs perpendicular to said cover plate;
said switching device can be displaced along a thrust axis which runs parallel to said cover plate;
said supporting element is displaced relative to said supporting plate along said thrust axis;
said first sensor electrode is linear in shape and said at least one second sensor electrode is block-shaped and is positioned adjacent to said first sensor electrode; and
said electrically conductive first electrode section of said signal element is linear in shape and said at least one electrically non-conductive part or said at least one electrically conductive part of said second electrode section of said signal element is block-shaped and is positioned adjacent to said electrically conductive first electrode section.

14. The operating device according to claim 8, wherein:
said switching device can be moved by a pressure actuation of said operating head in a direction perpendicular to said cover plate relative to said cover plate; and
said evaluation unit of said sensor device detects a change in distance between said first and second sensor electrodes and said signal element further based on the sensor signals of said sensor control system and identifies a pressure actuation of said operating head based on the detected change in distance.

15. The operating device according to claim 8,
wherein said sensor device is one of a plurality of sensor devices;
wherein said switching device is one of a plurality of movable switching devices which are each associated with one of the plurality of sensor devices; and
said plurality of sensor devices have a common sensor control system with a common sensor signal generator.

16. An electronic household appliance, comprising:
at least one operating device according to claim 8.
